(19) United States
(12) Patent Application Publication
(10) Pub. No.: US 2014/0077804 A1
(43) Pub. Date: Mar. 20, 2014

(54) Methods for Truncation Error Minimization in an MRI Device

(71) Applicants: Nikolaus Demharter, Dormitz (DE); Martin Nisznansky, Mohrendorf (DE)

(72) Inventors: Nikolaus Demharter, Dormitz (DE); Martin Nisznansky, Mohrendorf (DE)

(21) Appl. No.: 14/031,961

(22) Filed: Sep. 19, 2013

(30) Foreign Application Priority Data
Sep. 20, 2012 (DE) DE 102012216897.4

(51) Int. Cl. G01R 33/36

(52) U.S. Cl. CPC G01R 33/36
USPC 324/307; 324/318

(57) ABSTRACT

Devices and methods for the truncation of signal data in a system of a magnetic resonance imaging (MRI) device are provided. A device includes a demodulator that provides multiple truncation of signal data on a route between an input and an output of a system for the respective reduction of a bit width of signal data. Signal data to be truncated is inverted in each case before or after a truncation in only a part of the multiple truncations.

This application claims the benefit of DE 10 2012 216 897.4, filed on Sep. 20, 2012, which is hereby incorporated by reference.

### BACKGROUND

The present embodiments relate to methods and devices for truncation in a magnetic resonance imaging (MRI) device.

MRI devices for the examination of objects or patients by magnetic resonance tomography are known, for example, from DE10314215B4.

### SUMMARY

The scope of the present invention is defined solely by the appended claims and is not affected to any degree by the statements within this summary.

The present embodiments may obviate one or more of the drawbacks or limitations in the related art. For example, results of signal processing in a magnetic resonance imaging (MRI) device are optimized.

### BRIEF DESCRIPTION OF THE DRAWINGS

FIG. 1 illustrates exemplary bit width reduction by rounding without a statistical offset;

FIG. 2 illustrates exemplary statistical offsets with bit width reduction by truncations;

FIG. 3 shows one embodiment of a digital implementation of a demodulator in a magnetic resonance imaging (MRI) device with truncations; and

FIG. 4 is a schematic view of one embodiment of a magnetic resonance imaging (MRI) system.

### DETAILED DESCRIPTION

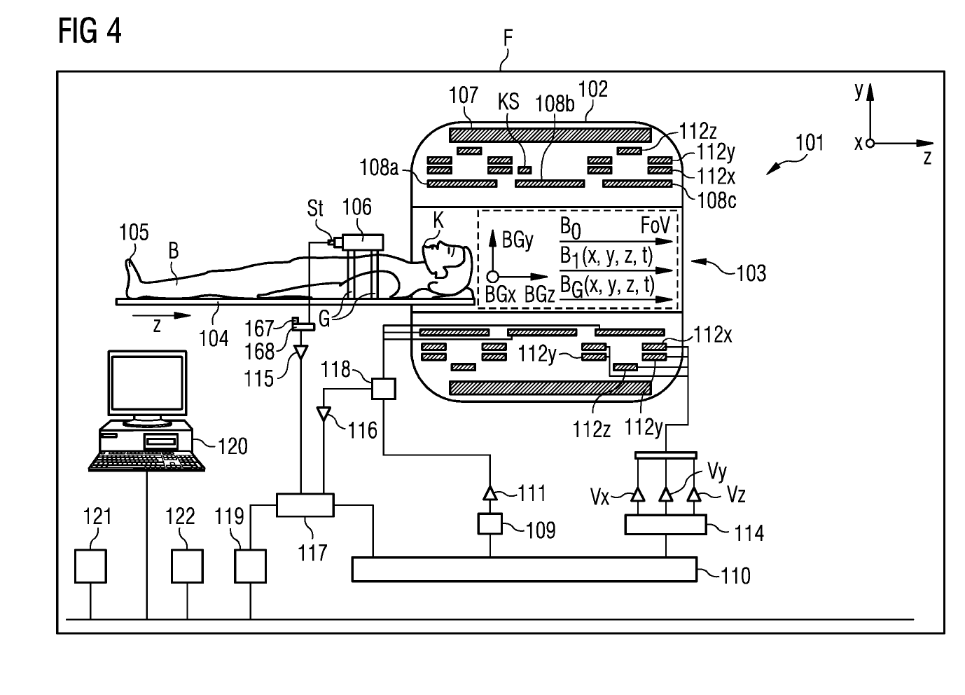

FIG. 4 shows a magnetic resonance imaging (MRI) device 101 (e.g., located in a shielded room or Faraday cage F) having a whole-body coil 102 with, for example, a tubular chamber 103 in which a patient bed 104 with a body 105(e.g., of an object to be examined such as a patient; with or without a local coil arrangement 106) may be moved in the direction of the arrow z in order to generate images of the patient 105 using an imaging method. A local coil arrangement 106, with which in a local region (e.g., a field of view (FOV)) of the MRI device, images of a section of the body 105 may be generated in the FOV, is arranged on the patient. Signals from the local coil arrangement 106 may be evaluated (e.g., converted into images, stored or displayed) by an evaluation mechanism (e.g., including elements 168, 115, 117, 119, 120, 121) of the MRI device 101, which may be connected to the local coil arrangement 106, for example, by coaxial cables or by radio (e.g., element 167).

To examine a body 105 (e.g., an object to be examined or a patient) with an MRI device 101 using magnetic resonance imaging, different magnetic fields that are attuned to one other as precisely as possible in terms of temporal and spatial characteristics are irradiated onto the body 105. A strong magnet (e.g., a cryomagnet 107) in a measuring cabin with, for example, a tunnel-shaped opening 103 generates a static strong main magnetic field Bₒ with a value of, for example, 0.2 tesla to 3 tesla or even more. A body 105 to be examined is positioned on a patient bed 104 and moved into a region of the main magnetic field B0 that is approximately homogeneous in the FOV. The nuclear spins of atomic nuclei of the body 105 are excited by magnetic high-frequency excitation pulses B1(x, y, z, t) that are radiated via a high-frequency antenna (and/or optionally a local coil arrangement) shown in FIG. 4 in very simplified form as a body coil 108 (e.g., a multi-part body coil 108a, 108b, 108c). High-frequency excitation pulses are generated, for example, by a pulse-generating unit 109 that is controlled by a pulse-sequence control unit 110. Following amplification by a high-frequency amplifier 111, the high-frequency excitation pulses are routed to the high-frequency antenna 108. The high-frequency system shown is only illustrated schematically. In other embodiments, more than one pulse-generating unit 109, more than one high-frequency amplifier 111 and a plurality of high-frequency antennas 108a, b, c are used in a magnetic resonance device 101.

The magnetic resonance device 101 also has gradient coils 112x, 112y, 112z, with which magnetic gradient fields B_{G}(x, y, z, t) for selective layer excitation and for spatial encoding of the measuring signal are irradiated during a measurement. The gradient coils 112x, 112y, 112z are controlled by a gradient-coil control unit 114 (and optionally via amplifiers Vx, Vy, Vz), which, like the pulse-generating unit 109, is connected to the pulse-sequence control unit 110.

Signals emitted by the excited nuclear spins (e.g., the atomic nuclei in the object to be examined) are received by the body coil 108 and/or at least one local coil arrangement 106, amplified by assigned high-frequency preamplifiers 116 and further processed and digitized by a receiving unit 117. The recorded measured data is digitized and stored as complex numerical values in a k-space matrix. An associated MR image may be reconstructed from the k-space matrix occupied by values using a multi-dimensional Fourier transformation.

For a coil that may be operated in both the transmitting and the receiving mode such as, for example, the body coil 108 or a local coil 106, the correct signal forwarding is regulated by an upstream transceiver switch 118.

An image-processing unit 119 generates an image from the measured data, which is displayed to a user via a control panel 120 and/or stored in a memory unit 121. A central computer unit 122 controls the individual system components.

In MR tomography, images with a high signal/noise ratio (SNR) are recorded with local coil arrangements (e.g., coils, local coils). The local coil arrangements are antenna systems that are attached in the immediate vicinity above (anterior) or below (posterior) or on or in the body 105. During an MR measurement, the excited nuclei induce a voltage into the individual antennas of the local coil. The induced voltage is amplified with a low-noise preamplifier (e.g., LNA, preamp) and routed to the receiving electronics. High-field systems (e.g., 1.5T-12T or more) are used to improve the signal/noise ratios, even in the case of high-resolution images. If it is possible to connect more individual antennas to an MR receiving system than there are receivers available, a switch matrix (e.g., an RCCS) is, for example, installed between the receiving antennas and receivers. This routes the currently active receiving channels (e.g., the receiving channels located precisely in the field of view of the magnet) to the available receivers. This makes it possible to connect more coil elements than there are receivers available, since, in the case of whole-body coverage, only the coils located in the FOV or in the homogeneity volume of the magnet may be read out.

A local coil arrangement 106 is, for example, generally the name given to an antenna system that may, for example, include one antenna element or, as an array coil, a plurality of antenna elements (e.g., coil elements). These individual antenna elements are embodied, for example, as loop antennas (loops), butterflies, flex coils or saddle coils. A local coil arrangement includes, for example, coil elements, a preamplifier, further electronics (e.g., baluns), a housing, supports and may include a cable with connectors with which the local coil arrangement is connected to the MRI device. A receiver 168 attached to the device filters and digitizes a signal received from a local coil 106 (e.g., by radio), and transfers the data to a digital signal-processing mechanism that may derive an image or spectrum from the data obtained by a measurement and makes the image or spectrum available to the user, for example, for subsequent diagnosis and/or storage.

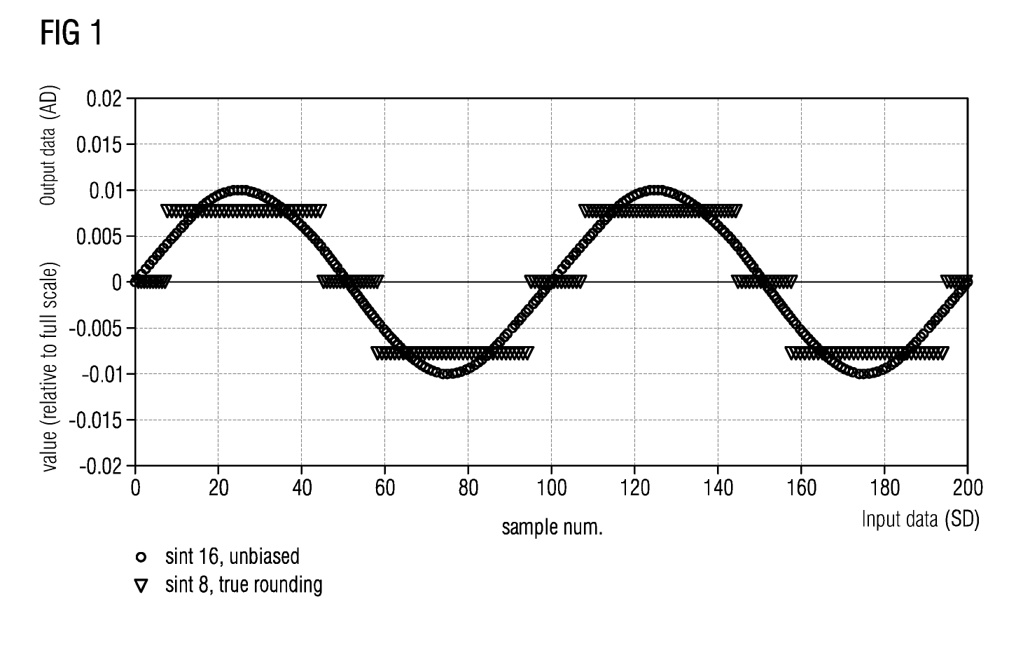

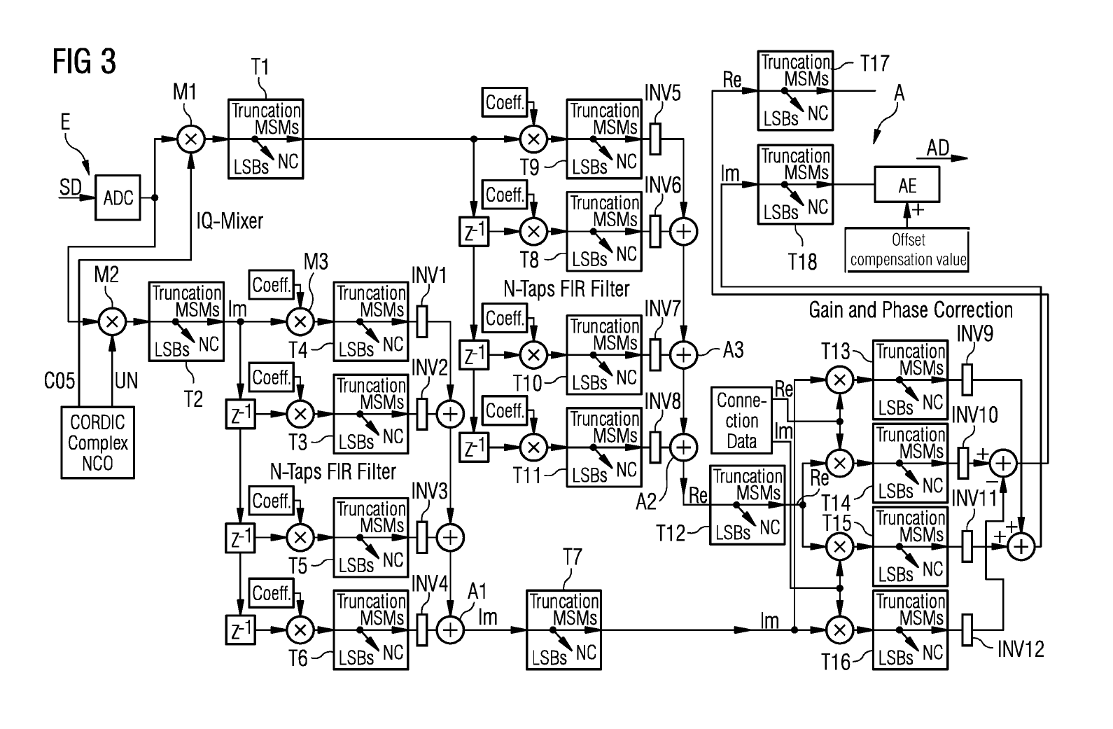

In the case of fixed-point mathematical operations, it may be provided multiple times that in each case after a step, a processed bit width (e.g., the processed signal data SD) is reduced. If this is performed as shown in FIG. 1 using rounding, the result of the rounding (e.g., in FIG. 1, reference character “sint8 true rounding,” translated: mathematical rounding) for all output signals AD shown in each case as a triangle (e.g., reference character “value (relative to full scale)”) of a system (e.g., the system of FIG. 3) for a series shown, for example, of 200 “sample-run” (e.g., sample run of a sampling of local coil received data etc.), pieces of input data SD (e.g., in FIG. 1, reference character “saint16 unbiased” for all input signals shown in each case as circles) are symmetrical and not affected by an offset.

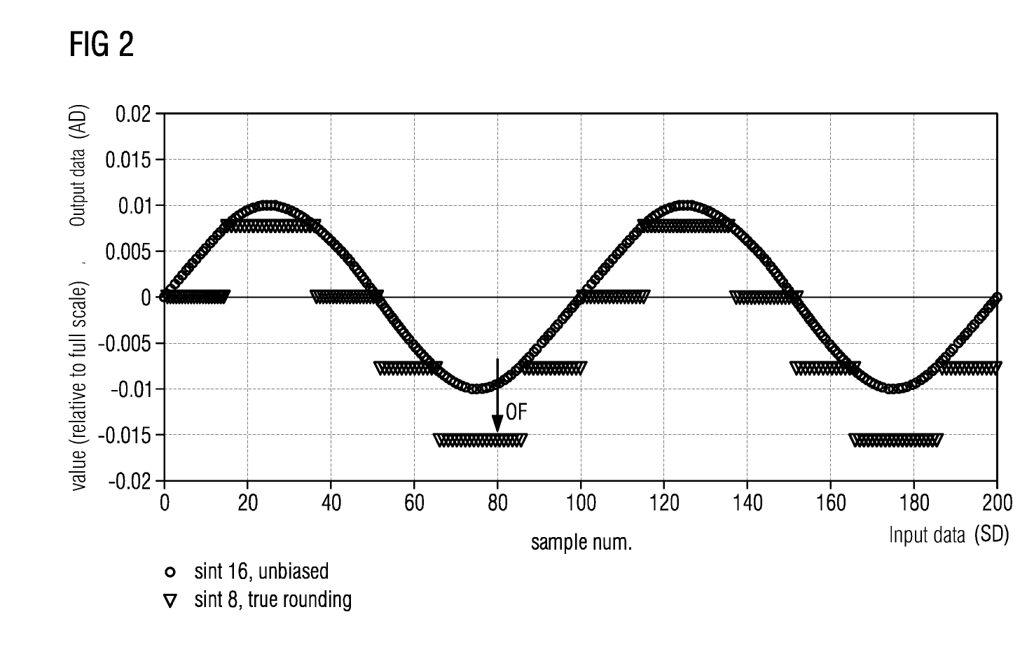

If, for cost consideration, the bit width reduction (instead of with rounding) is performed with a simpler truncation (e.g., translated: mathematical rounding; omission of positions behind the decimal point after a selected position LSB), the output data (e.g., in FIG. 2, reference character “sint8 truncated only” (translated approximately: position-clipping-rounding) for some or all output signals of a system depicted as a triangle such as, for example, as shown in FIG. 3 is on average or partially affected by an offset. This offset is evident in FIG. 2 (e.g., as a comparison with FIG. 1; as a displacement of the values downward by an offset OF) and corresponds in the case of all or some parts of the data to 0.5 LSB (e.g., half of the maximum value of the least significant byte LSB) of the output signal. With a variety of applications, this offset may be undesirable and disruptive.

Since each rounding uses an additional addition (e.g., with 0.5*LSB of the output) compared to simple truncation, complexity of the rounding may almost be the same as the complexity of the actual arithmetical operations.

FIG. 3 shows by way of example a digital implementation of a demodulator (e.g., demodulator of a MRI device for HF data SD received from a body with a local coil). FIG. 3 shows how often clipping is performed by truncation in truncation mechanisms T1, T2, T3, T4, T5, T6, T7, T8, T9, T10, T11, T12, T13, T14, T15, T16, T17, T18 (e.g., processors and/or field-programmable gate arrays). Input data widths in subsequent arithmetic operations (e.g., with multipliers M1, M2, M3 and adders A1, A2, A3) are limited. An output of an addition (e.g., with adders A1, A2, A3) is wider by a bit and in the case of multiplication (e.g., with multipliers M1, M2, M3) with coefficients (e.g., “Coeff”), even includes the sum of the two input bit widths of the multiplication.

At the output, the effect of all processing stages is superimposed.

The rounding options partially available in field-programmable gate array (FPGA) macros may not be functionally usable. If these macros are compiled on the basis of logic cells, the macros use exactly the same logic cells as if the macros were directly encoded. Once again, the rounding corresponds to an addition with 0.5 LSB.

If these macros are available on the basis of hard macros with limited flexibility, the usability of the macros is limited to exactly the application envisaged by the manufacturer. However, this application is may not be the same as the actual application so that the rounding function may not be implemented within a hard macro. The FPGA manufacturer limits the flexibility of hard macros, since otherwise hard macros use a larger chip area.

Two embodiments for compensating the truncation offset (e.g., as offset compensation mechanism (INV1-INV12; “Coeff”; AE) for the compensation of an offset (OF)), which may in each case be used individually or also in combination, are provided. One embodiment provides the minimization of superimposition by inversion at suitable places in the processing chain. Another embodiment provides compensation of the offset by an individual sum at the input or output. In the example in FIG. 3, input compensation after an IQ mixer may be provided, since an offset at the input would be convoluted by the mixing in the mixing frequency of the NCO.

The principle of minimization by superimposition is based on the fact that during truncation, a negative (e.g., common-mode) offset occurs. If the signal is never inverted, the (scaled) errors are added to each individual processing step unidirectionally. The maximum of the error (e.g., offset) occurs at the end of the processing chain.

If, instead, at suitable places (e.g., at even numbers and/or at each second truncation along the processing of a signal and/or at each second truncation during the parallel processing of a signal), the signal to be processed is inverted (e.g., by either inverters INV1, INV2, INV3, INV4, INV5, INV6, INV7, INV8, INV9, INV10, INV11, INV12 or inversion (and inverted storage for all applications of the coefficient) of the coefficients Coeff for multiplications in a negative value), the actual output signal does not change, but the offsets that occur at the truncations mutually compensate each other. In an ideal case, complete compensation is achieved. Otherwise, good compensation is achievable.

In terms of digital technology, signal inversion may be very low on overheads and may even be achieved in that the coefficients referred to as Coeff shown in FIG. 3 are applied in a processing step (e.g., in which the signal is multiplied during the processing with a factor Coeff) in inverted form (e.g., with a changed preceding sign). The offset compensation at the input or output also results from the superimposition of the error offsets.

This offset may be summarily measured at the output. Alternatively, the offset may be determined by calculation since the offset is completely or extensively dependent upon the structure of the processing chain (and the size of the coefficients that cause scaling). The offset is independent of the actual signal. Therefore, this offset may be compensated at the output by the addition of a constant value.

This correction offset may also alternatively be transformed at the input (or any other suitable place within the processing chain) and compensated there. However, a transformation beyond, for example, a mixer stage, is not simple. In this case, the compensation signal would be mixed as well.

One possible advantage may result from the great saving on logic, since a plurality of adders may be saved for the rounding. This makes it possible to use smaller and cheaper FPGAs or even to implement the complete calculating chain in a single FPGA.

Further savings may result from the power consumption and cooling due to the savings on logic.

This enables a function to be ultimately implemented in a less expensive way. The potential savings may be up to 50%.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for processing signal data in a system of a magnetic resonance imaging (MRI) device, the method comprising:
providing multiple truncation of signal data on a route between an input and an output of the system for the respective reduction of a bit width of the signal data in the system; and
providing, with at least one compensation mechanism, at least one compensation of offsets of the signal data induced by truncation.

2. The method of claim 1, wherein system of the MRI device comprises a demodulator.

3. The method of claim 1, wherein the providing of the at least one compensation of offsets comprises inverting signal data to be truncated before or after the truncation in only a part of the multiple truncations.

4. The method of claim 3, further comprising inverting, at several sections of an even number, the signal to be processed before the truncation of the signal to be processed.

5. The method of claim 1, further comprising inverting the signal to be processed before the truncation in half of the cases of multiple truncations.

6. The method of claim 1, wherein one of the multiple truncations of signal data takes place during a processing at different places in the system between the input of the system and the output of the system.

7. The method of claim 3, wherein by truncation in only one part of the cases of the multiple truncations, mutually occurring offsets at several truncations compensate each other in full or partially.

8. The method of claim 1, further comprising inverting a signal to be processed by a computing operation before truncation of the signal to be processed,
wherein coefficients to be multiplied with the signal data with a multiplier are used in inverted form, negative form, or inverted and negative form.

9. The method of claim 1, wherein an offset at the output of the system is measureable or determinable by calculation or from a structure of a processing chain, a size of coefficients that cause a scaling, or a combination thereof.

10. The method of claim 1, wherein with all or a part of the signal data, during processing at different places in the system, truncation takes place several times between the input of the system and the output of the system.

11. The method of claim 1, wherein the providing of the at least one compensation of offsets comprises compensating for an offset measured by summation or determined by calculation at least once at the output of the system of the MRI device, in which the multiple truncation of the signal data takes place on the route between the input and the output of the system, the compensating comprising adding a constant positive or negative value.

12. The method of claim 11, wherein the compensating comprises adding the constant positive or negative value at the input, the output, or the input and the output.

13. A device for processing signal data in an imaging magnetic resonance imaging (MRI) device system, the device comprising:
truncation mechanisms between an input and an output of the device, the truncation mechanisms operable to limit a bit width of the signal data by truncation; and
at least one offset compensation mechanism operable to compensate offsets induced by truncation of the signal data.

14. The device of claim 13, further comprising inversion mechanisms operable to invert the signal data,
wherein each of the inversion mechanisms is positioned upstream or downstream of only a part of the truncation mechanisms as an offset compensation mechanism.

15. The device of claims 13, wherein a plurality of places are provided in order in each case to invert a signal to be processed before or after truncation.

16. The device of claim 15, wherein the plurality of places are provided in order in each case to invert the signal to be processed on each second truncation of the signal to be processed on a route between the input and output.

17. The device of claim 13, wherein in half of the cases of the multiple truncations of a signal, truncation of a signal to be processed is provided between the input and output.

18. The device of claim 13, wherein the truncation mechanisms are provided at more than two places in the system between the input of the system and the output of the system.

19. The device of claim 13, wherein the device is configured such that, by truncation in only one part of the cases of the multiple truncations, mutually occurring offsets at a plurality of truncations compensate each other in full or partially.

20. The device of claim 14, wherein a signal to be processed by a computing operation is in each case inverted before or after the truncation, and
wherein coefficients to be multiplied with the signal data with a multiplier are used in inverted form, negative form, or inverted and negative form of the coefficients.

21. The device of claim 13, wherein the device is configured such that an offset at the output of the system is measurable or determinable by calculation from a structure of a processing chain, size coefficients that cause scaling, or a combination thereof.

22. The device of claim 13, wherein during processing, the truncation mechanisms are operable to provide truncation a plurality of times on the signal data at different places in the device between the input of the device and the output of the device.

23. The device of claim 13, further comprising an addition mechanism as an offset compensation mechanism,
wherein the addition mechanism is configured to compensate an offset measured by summation or determined by calculation at an output of a system of the MRI device, in which multiple truncation of the signal data takes place on a route between an input of the system and the output of the system, by addition of a stored constant positive or negative value.

24. The device of claim 23, wherein the addition mechanism is configured to add the stored constant positive or negative value at the input of the system or the output of the system.
